(19) United States
(12) Patent Application Publication
(10) Pub. No.: US 2024/0035899 A1
(43) Pub. Date: Feb. 1, 2024

(54) ELECTRONIC CIRCUIT DEVICE AND METHOD FOR MEASURING TEMPERATURE OF ELECTRONIC CIRCUIT DEVICE

(71) Applicant: FURUNO ELECTRIC CO., LTD., Hyogo (JP)

(72) Inventor: Takuji YASUMOTO, Nishinomiya (JP)

(73) Assignee: FURUNO ELECTRIC CO., LTD., Hyogo (JP)

(21) Appl. No.: 18/478,489

(22) Filed: Sep. 29, 2023

Related U.S. Application Data
(63) Continuation-in-part of application No. PCT/JP2022/007300, filed on Feb. 22, 2022.

(30) Foreign Application Priority Data
Mar. 31, 2021 (JP) 2021-058988

(51) Int. Cl. G01K 7/20; G01K 15/00

(52) U.S. Cl. CPC G01K 7/203; G01K 15/002; G01K 15/005; G01K 2215/00; G01K 2217/00

(57) ABSTRACT

A temperature of an electronic circuit device such as an integrated circuit is measured with high accuracy. The electronic circuit device (10) includes a main processor (20) and a temperature measurement module (30). The main processor (20) can execute predetermined signal processing. The temperature measurement module (30) generates a signal having a correspondence relationship with the temperature of the main processor (20) under a mode in which the temperature measurement module is driven at a predetermined low power consumption or less and the thermal resistance between the temperature measurement module and the main processor (20) is a predetermined thermal resistance value or less.

### TECHNICAL FIELD

This application is a continuation-in-part application of PCT International Application No. PCT/JP2022/007300, which was filed on Feb. 22, 2022, and which claims priority to Japanese Patent Application No. JP2021-058988 filed on Mar. 31, 2021, the entire disclosures of each of which are herein incorporated by reference for all purposes.

### TECHNICAL FIELD

Embodiments of the present disclosure relate to the field of electronic circuits, and more particularly, a system and a method for measuring a temperature of an electronic circuit device such as an IC.

### BACKGROUND

Patent Literature 1 describes a method for measuring a temperature of an integrated circuit.

Patent Literature 1: Japanese Patent Application Publication No. 2014 -510268.

However, in the above document, the temperature of the integrated circuit cannot be accurately measured.

Hence, there is a need for an improved system and method for measuring a temperature of an electronic circuit device which addresses the aforementioned issue(s).

### SUMMARY

Accordingly, an object of the present disclosure is to accurately measure the temperature of an electronic circuit device such as an integrated circuit.

### BRIEF DESCRIPTION

In accordance with an embodiment of the present disclosure, an electronic circuit device is provided. The electronic circuit device includes a main processor module (processing circuitry) configured to execute predetermined signal processing. Further, the electronic circuit device includes a temperature measurement module (a thermometer) configured to generate an oscillation signal having an oscillation frequency in correspondence with a temperature of the main processor module under a mode. The temperature measurement module is driven at a predetermined low power consumption value or less. Further, a thermal resistance between the temperature measurement module and the main processor module is a predetermined thermal resistance value or less.

In accordance with an embodiment of the present disclosure, a method for measuring temperature of an electronic circuit device is provided. The method includes executing predetermined signal processing. The method also includes generating an oscillation signal having an oscillation frequency in correspondence with a temperature of the main processor module under a mode, when the temperature measurement module is driven at a predetermined low power consumption value or less and when a thermal resistance between the temperature measurement module and the main processor module is a predetermined thermal resistance value or less.

In accordance with an embodiment of the present disclosure, a non-transitory computer-readable storage medium having stored thereon machine-readable instructions that, when executed by one or more processors of an apparatus, cause the apparatus to perform a method is provided. The method includes executing predetermined signal processing. Further, the method includes driving a temperature measurement module at a predetermined low power consumption value or less. Furthermore, the method includes generating a signal in correspondence with a temperature of the main processor module under a mode when a thermal resistance between the temperature measurement module and the main processor module is a predetermined thermal resistance value or less.

To further clarify the advantages and features of the present disclosure, a more particular description of the disclosure will follow by reference to specific embodiments thereof, which are illustrated in the appended figures. It is to be appreciated that these figures depict only typical embodiments of the disclosure and are therefore not to be considered limiting in scope. The disclosure will be described and explained with additional specificity and detail with the appended figures.

### BRIEF DESCRIPTION OF THE DRAWINGS

The disclosure will be described and explained with additional specificity and detail with the accompanying figures in which:

FIG. 1 is a functional block diagram of an electronic circuit device in accordance with an embodiment of the present disclosure;

FIG. 2 is a graph showing an example of a temperature frequency characteristic of an RC oscillator in accordance with an embodiment of the present disclosure;

FIG. 3 is a flowchart illustrating an example of advance preparation of the temperature measurement method of FIG. 1 in accordance with an embodiment of the present disclosure;

FIG. 4 is a flowchart illustrating an example of a temperature measurement method in accordance with an embodiment of the present disclosure;

FIG. 5 is a functional block diagram of an electronic circuit device in accordance with another embodiment of the present disclosure; and

FIG. 6 is a functional block diagram of an electronic circuit device in accordance with yet another embodiment of the present disclosure.

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show only those specific details that are pertinent to understanding the embodiments of the present disclosure so as not to obscure the figures with details that will be readily apparent to those skilled in the art having the benefit of the description herein.

### DETAILED DESCRIPTION

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated system, and such further applications of the principles of the disclosure as would normally occur to those skilled in the art are to be construed as being within the scope of the present disclosure.

The terms “comprises”, “comprising”, or any other variations thereof, are intended to cover a non-exclusive inclusion, such that a process or method that comprises a list of steps does not include only those steps but may include other steps not expressly listed or inherent to such a process or method. Similarly, one or more devices or subsystems or elements or structures or components preceded by “comprises . . . a” does not, without more constraints, preclude the existence of other devices, sub-systems, elements, structures, components, additional devices, additional sub-systems, additional elements, additional structures or additional components. Appearances of the phrase “in an embodiment”, “in another embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are only illustrative and not intended to be limiting.

In the following specification and the claims, reference will be made to a number of terms, which shall be defined to have the following meanings. The singular forms “a”, “an”, and “the” include plural references unless the context clearly dictates otherwise.

### First Embodiment

A temperature measurement technique of the electronic circuit device according to the first embodiment of the present disclosure will be described with reference to the drawings.

### [Configuration of Electronic Circuit Device (10)]

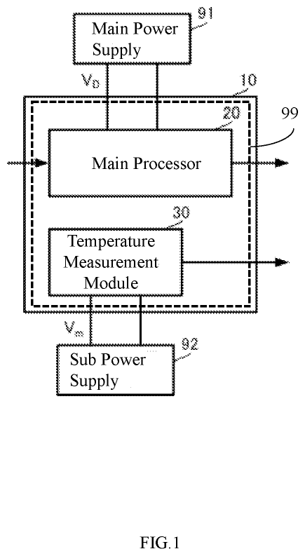

FIG. 1 is a functional block diagram of an electronic circuit device according to a first embodiment. As illustrated in FIG. 1, the electronic circuit device (10) may include a main processor [processing circuitry] (20) and a temperature measurement module [thermometer] (30). The thermometer (30) can be implemented in the processing circuitry (99).

Being not illustrated, the electronic circuit device (10) may be formed of a semiconductor IC. More specifically, the electronic circuit device (10) may include a substrate, a plurality of electronic circuit elements, a resin mold, and an external connection terminal. The substrate may be formed of, for example, a semiconductor (wafer). The substrate may be a substrate (circuit board) instead of a wafer. The plurality of electronic circuit elements may be formed or mounted on the substrate. The resin mold may cover the substrate and the plurality of electronic circuit elements.

The external connection terminal may be a terminal that conducts the external connection electrode of the substrate to the outside, and may be formed by a pin, a solder bump, or the like. The external connection terminal may be used for input and output of various signals, application of the drive voltage VD and the measurement voltage Vm, and the like, described later.

The main processor (20) and the temperature measurement module (30) may be realized by a plurality of electronic circuit elements, more precisely, implemented by processing circuitry (20). The main processor (20) and the temperature measurement module (30) may be filled in a resin mold.

The main processor (20) and the temperature measurement module (30) may be disposed adjacent to each other. More specifically, the temperature measurement module (30) may be disposed at a position affected by the temperature of the main processor (20). That is, the thermal resistance between the main processor (20) and the temperature measurement module (30) may be equal to or less than a predetermined thermal resistance value, and the temperature measurement module (30) may have substantially the same temperature as the main processor (20). The main processor (20) and the temperature measurement module (30) may be formed on the same substrate.

The main processor (20) may be supplied with the drive voltage VD from the main power supplier (91). The main processor (20) may be driven by the drive voltage VD, perform predetermined signal processing on an input signal, for example, and output the processed signal. The main processor (20) may be driven with low power consumption (may be in a low power consumption driving state), in addition to the mode of driving with rated power consumption (power dissipation).

The temperature measurement module (30) may be supplied with the measurement voltage Vm from the temperature measurement power supplier (92). The measurement voltage Vm may be lower than the drive voltage VD. More specifically, the measurement voltage Vm may be equal to or lower than the drive voltage VD when the main processor (20) is driven with low power consumption. Furthermore, the measurement voltage Vm may be set so that the temperature rise of the temperature measurement module (30) due to the measurement voltage Vm does not affect the temperature measurement of the main processor (20). For example, the measurement voltage Vm may be set such that the temperature rise during temperature measurement is less than 0.1° C. [degree Celsius]. The specific threshold value of the temperature rise may be an example, and may be appropriately set so as to ensure the accuracy of the temperature measurement.

The temperature measurement module (30) may include an oscillator. The temperature measurement module (30) may include, for example, an RC oscillator. The temperature measurement module (30) may oscillate at an oscillation frequency in correspondence with an ambient temperature and output an oscillation signal.

In this configuration, the heat source that affects the temperature measurement module (30) by increasing the thermal resistance of the substrate and the resin mold may be substantially the main processor (20). Therefore, the temperature measurement module (30) may generate and output an oscillation signal having an oscillation frequency in correspondence with a temperature of the main processor (20).

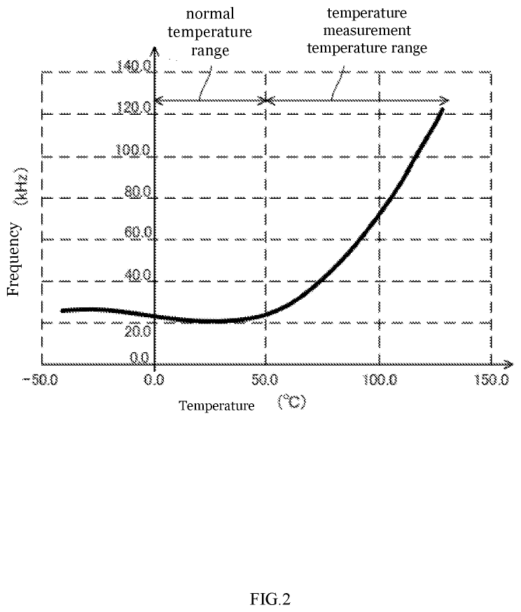

FIG. 2 is a graph illustrating an example of a temperature frequency characteristic of the RC oscillator. In the example illustrated in FIG. 2, the temperature frequency characteristic of the RC oscillator may have a normal temperature range of about 50° C. [degree Celsius] or less and a temperature measurement temperature range higher than about 50° C. [degree Celsius]. In the normal temperature range, the frequency hardly changes even when the temperature changes. In the temperature measurement temperature range, the frequency may increase as the temperature increases. The change amount of the frequency due to the temperature change in the temperature measurement temperature range may be larger than the change amount of the frequency due to the temperature change in the normal temperature range. Further, in the temperature measurement temperature range, the frequency and the temperature may have a one-to-one relationship.

Therefore, by detecting the oscillation frequency of the oscillation signal in the temperature measurement temperature range, the temperature of the main processor (20) may be measured with a predetermined accuracy.

That is, even in the main processor (20) covered with the resin mold, the temperature of the main processor (20) may be measured almost directly without estimating and measuring the temperature from the temperature outside the electronic circuit device (10). Accordingly, the temperature of the main processor (20) may be measured with higher accuracy.

Accordingly, for example, a temperature margin at the time of designing the electronic circuit device (10) may be reduced. Therefore, the entire apparatus including the electronic circuit device (10) may be designed with more appropriate specifications according to the use environment and specifications.

In the above-described embodiment, an aspect in which the temperature measurement module (30) is realized by the RC oscillator has been described. However, the temperature measurement module (30) may be adopted as long as it has a temperature range in which the oscillation frequency changes depending on the temperature and the temperature and the oscillation frequency have a one-to-one relationship.

Further, the temperature measurement module (30) may not have a linear relationship between the temperature and the frequency as long as the relationship between the temperature and the frequency is known as illustrated in FIG. 2. Accordingly, the temperature measurement module (30) may not adjust the temperature and the frequency to have a linear relationship. The temperature measurement module (30) may not be limited to the RC oscillator and may include an LC oscillator.

### [Method of Measuring Temperature of Electronic Circuit Device (10)]

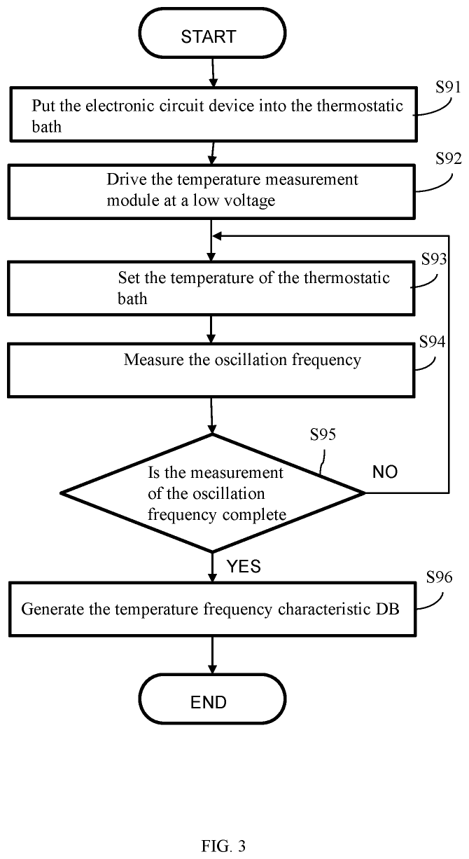

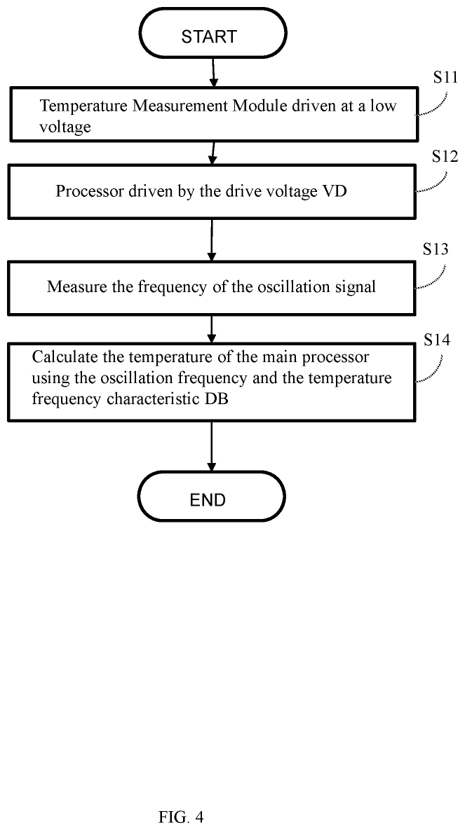

In the above-described configuration, when the temperature of the main processor (20) is measured, a method illustrated in FIGS. 3 and 4 below may be used as an example. FIG. 3 is a flowchart illustrating an example of advance preparation of the temperature measurement method according to the first embodiment. FIG. 4 is a flowchart illustrating an example of a temperature measurement method according to the first embodiment.

### [Preparation]

As shown in FIG. 3, the electronic circuit device (10) may be put into the thermostatic bath (S91). The temperature measurement module (30) of the electronic circuit device (10) may be driven at a low voltage (measurement voltage Vm) (S92).

Next, the temperature of the thermostatic bath may be set to stabilize the temperature of the thermostatic bath and the temperature of the electronic circuit device (10) (S93). After the temperature of the thermostatic bath may be stabilized, the oscillation frequency of the oscillation signal output from the temperature measurement module (30) is measured (S94). Then, the temperature of the thermostatic bath and the oscillation frequency may be recorded.

The temperature of the thermostatic bath and the electronic circuit device (10) may be changed until the measurement of the oscillation frequency with respect to the temperature is completed in the entire temperature measurement temperature range (S95: YES), and the oscillation frequency may be measured for each changed temperature.

When the measurement of the oscillation frequency with respect to the temperature may be completed over the entire temperature measurement temperature range (S95: NO), a temperature frequency characteristic DB (database) having a relationship between the measured oscillation frequency and the temperature may be generated (S96). Then, the calibration of the oscillation frequency and the temperature may be completed. The thermal resistance between the main processor (20) and the temperature measurement module (30) may not affect the temperature calibration.

### [Temperature Measurement of Electronic Circuit Device (10)]

As shown in FIG. 4, the temperature measurement module (30) may be driven at a low voltage (measurement voltage Vm) (S11). The main processor (20) may be driven by the drive voltage VD (S12).

The frequency (oscillation frequency) of the oscillation signal may be measured (S13). The temperature of the main processor (20) may be calculated using the oscillation frequency and the temperature frequency characteristic DB (S14).

Accordingly, the temperature of the main processor (20) formed inside the semiconductor IC subjected to resin molding or the like may be measured with high accuracy.

### Second Embodiment

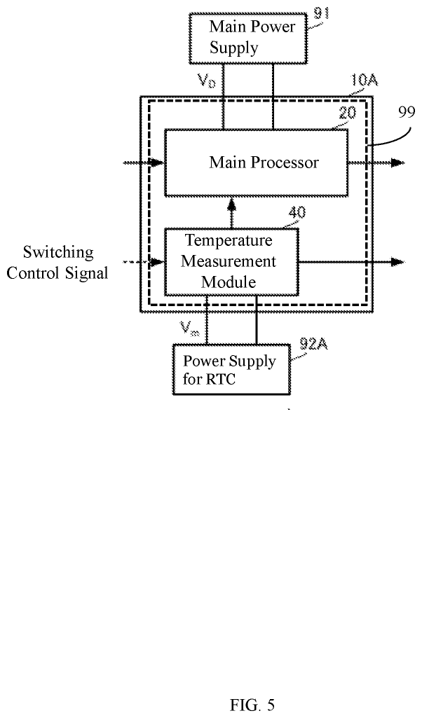

A temperature measurement technique of an electronic circuit device according to a second embodiment of the present disclosure may be described with reference to the drawings. FIG. 5 is a functional block diagram of the electronic circuit device according to the second embodiment.

As illustrated in FIG. 5, the electronic circuit device (10) according to the second embodiment may be different from the electronic circuit device (10) according to the first embodiment where the temperature measurement module (30) may be replaced with the RTC signal generator (40). Other configurations of the electronic circuit device (10) may be the same as those of the electronic circuit device (10), and the description of the same portions has been omitted.

The electronic circuit device (10) includes an RTC signal generator (40). The RTC is a real-time clock. The RTC signal generator (40) includes an RC oscillator.

The RTC signal generator (40) may generate an RTC signal based on the oscillation signal output from the RC oscillator. The RTC signal generator (40) may output the RTC signal to the main processor (20). At this time, the main processor (20) may be in a state where the power supply is cut off or where an input clock is stopped, for example.

The RTC signal generator (40) may output the oscillation signal as a temperature measurement signal.

More specifically, for example, a switching control signal may be input to the RTC signal generator (40). The switching control signal may be a control signal for switching whether the RTC mode is the temperature measurement mode.

When the RTC mode may be set by the switching control signal, the RTC signal generator (40) may output the RTC signal based on the oscillation signal to the main processor (20). At this time, the electronic circuit device (10) may be operating in the normal temperature range. Therefore, as shown in FIG. 2, the difference in the oscillation frequency depending on the temperature may be small. Accordingly, the RTC signal having a stable desired accuracy may be input to the main processor (20).

On the other hand, at the time of temperature measurement, the RTC signal generator (40) may set the temperature measurement mode by the switching control signal and output the oscillation signal. At this time, the electronic circuit device (10) may be set in the temperature measurement temperature range. Therefore, as shown in FIG. 2, the oscillation frequency may change in accordance with the temperature, and the oscillation frequency and the temperature have a one-to-one relationship. Accordingly, the temperature of the main processor (20) may be measured with high accuracy at the time of temperature measurement.

### Third Embodiment

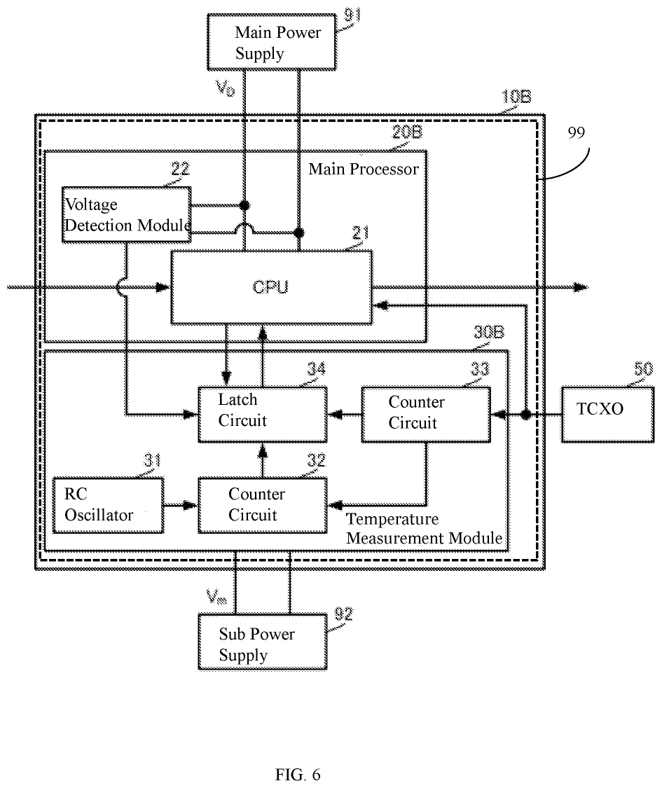

A temperature measurement technique of an electronic circuit device according to a third embodiment of the present disclosure will be described with reference to the drawings. FIG. 6 is a functional block diagram of the electronic circuit device according to the third embodiment.

As illustrated in FIG. 6, the electronic circuit device (10B) according to the third embodiment may be different from the electronic circuit device (10) according to the first embodiment in the specific configurations of the main processor (20B) and the temperature measurement module [thermometer] (30B). Other configurations of the electronic circuit device (10B) may be the same as those of the electronic circuit device (10), and the description of the same portions has been omitted.

The electronic circuit device (10B) may include a main processor (20B) and a temperature measurement module (30).

The main processor (20B) may include a CPU (21) and a voltage detection module (22). The CPU (21) may execute various types of signal processing executed by the main processor (20B). Further, the CPU (21) may output the output data of the latch circuit (34) of the temperature measurement module (30B) to the outside.

The temperature measurement module (30B) may include an RC oscillator (31), a counter circuit (32), a counter circuit (33), and a latch circuit (34).

The RC oscillator (31) may generate an oscillation signal having an oscillation frequency in correspondence with an ambient temperature (mainly the temperature of the main processor (20B)) and output the oscillation signal to the counter circuit (32).

The counter circuit (32) may count based on the oscillation signal and output a count value to the latch circuit (34).

The counter circuit (33) may frequency-divide a high-precision frequency signal from the external TCXO (50) to generate a latch signal and a reset signal. The counter circuit (33) may output a reset signal to the counter circuit (32) at a reset timing of measurement. The counter circuit (33) may output a latch signal to the latch circuit (34) at a predetermined cycle during measurement.

The latch circuit (34) may latch the count value of the counter circuit based on the input timing of the latch signal from the counter circuit (33). The latch circuit (34) may output the latched count value to the CPU (21). Upon receiving a voltage detection signal from the voltage detection unit of the main processor (20), the latch circuit (34) may stop the latch operation. The latch circuit (34) may execute the latch operation when the latch stop is released from the CPU (21).

In such a configuration, temperature measurement may be performed as follows.

### [Advance Preparation]

The electronic circuit device (10B) may be placed in a thermostatic bath. A measurement voltage Vm is supplied from the temperature measurement power supplier (92) to drive the temperature measurement module (30B).

The counter circuit (32) may start counting by the clock of the RC oscillator (31).

The TCXO (50) may be activated to input a high-precision frequency signal. The counter circuit (33) may generate a reset signal and a latch signal based on the high-precision frequency signal.

The counter circuit (32) may reset the count at the input timing of the reset signal.

The latch circuit (34) may latch the count value from the counter circuit (32) at the input timing of the latch signal.

Next, the drive voltage VD may be supplied from the main power supplier (91) to the main processor (20B). Upon detecting the drive voltage VD, the voltage detection module (22) may output a voltage detection signal to the latch circuit (34).

The latch circuit (34) may stop the latch operation based on the input of the voltage detection signal, and output the counter value at that time to the CPU (21).

The CPU (21) may convert the counter value into, for example, serial data and output the serial data.

By repeating this operation while changing the temperature of the thermostatic bath, the above-described temperature frequency characteristic DB may be obtained.

### [Temperature Measurement of Electronic Circuit Device (10B)]

When measuring the temperature of the electronic circuit device (10B) after completion of the above-described advance preparation, the CPU (21) may output a release signal for releasing the stop of the latch operation to the latch circuit (34). The latch circuit (34) may resume the latch operation based on the release signal.

Thereafter, the latch circuit may latch the count value output from the counter circuit (32) for each cycle determined by the reset signal and the latch signal, and output the count value to the CPU (21). The CPU (21) sequentially may convert the input count value into serial data and outputs the serial data.

This count value may depend on the current temperature of the main processor (20B). Therefore, by executing such processing, the temperature of the main processor (20B) may be measured with high accuracy.

By using this configuration, the electronic circuit device (10B) may use an external connection terminal used for normal processing as an output terminal of serial data for temperature measurement. As a result, an external connection terminal for temperature measurement may not be separately provided as the electronic circuit device (10B).

### [Application Example of Electronic Circuit Device]

The electronic circuit device having the above-described configuration may be applied to, for example, an IC for positioning. That is, the main processor may realize an RF receiving unit, a capturing and tracking unit, and a positioning calculation.

At this time, if the electronic circuit device (10A) may use the RTC signal generator (40), a general RTC signal for positioning may be used as a signal output from the RTC signal generator (40). In other words, the electronic circuit device (10A) may measure the temperature by the RTC signal used for positioning.

In the case of the electronic circuit device (10B) that receives an input from the TCXO (50), the TCXO (50) may be used for capturing and tracking a positioning signal, and the electronic circuit device (10B) may measure a temperature using an output signal of the TCXO (50) for capturing and tracking.

In each of the above-described embodiments, the main power supplier (91) and the temperature measurement power supplier (92) may be independent of each other. However, the main power supplier (91) and the temperature measurement power supplier (92) may be common, and different voltages may be supplied to the main processor and the temperature measurement module. However, since the main power supplier (91) and the temperature measurement power supplier (92) are independent of each other, for example, the above-described various types of power supply control may be easily performed.

The techniques described in this disclosure may be implemented, at least in part, in hardware, software, firmware, or any combination thereof. For example, various aspects of the described techniques may be implemented within one or more processors, including one or more microprocessors, digital signal processors (DSPs), application-specific integrated circuits (ASICs), field-programmable gate arrays (FPGAs), or any other equivalent integrated or discrete logic circuitry, as well as any combinations of such components. The term “processor” or “processing subsystem” may generally refer to any of the foregoing logic circuitry, alone or in combination with other logic circuitry, or any other equivalent circuitry. A control unit including hardware may also perform one or more of the techniques of this disclosure.

Such hardware, software, and firmware may be implemented within the same device or within separate devices to support the various techniques described in this disclosure. In addition, any of the described units, modules, or components may be implemented together or separately as discrete but interoperable logic devices. Depiction of different features as modules or units is intended to highlight different functional aspects and does not necessarily imply that such modules or units must be realized by separate hardware, firmware, or software components. Rather, functionality associated with one or more modules or units may be performed by separate hardware, firmware, or software components, or integrated within common or separate hardware, firmware, or software components.

It will be understood by those skilled in the art that the foregoing general description and the following detailed description are exemplary and explanatory of the disclosure and are not intended to be restrictive thereof.

While specific language has been used to describe the disclosure, any limitations arising on account of the same are not intended. As would be apparent to a person skilled in the art, various working modifications may be made to the method in order to implement the inventive concept as taught herein.

The figures and the foregoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, the order of processes described herein may be changed and are not limited to the manner described herein. Moreover, the actions of any flow diagram need not be implemented in the order shown; nor do all of the acts need to be necessarily performed. Also, those acts that are not dependent on other acts may be performed in parallel with the other acts. The scope of embodiments is by no means limited by these specific examples.

### [Terminology]

It is to be understood that not necessarily all objects or advantages may be achieved in accordance with any particular embodiment described herein. Thus, for example, those skilled in the art will recognize that certain embodiments may be configured to operate in a manner that achieves or optimizes one advantage or group of advantages as taught herein without necessarily achieving other objects or advantages as may be taught or suggested herein.

All of the processes described herein may be embodied in, and fully automated via, software code modules executed by a computing system that includes one or more computers or processors. The code modules may be stored in any type of non-transitory computer-readable medium or other computer storage device. Some or all the methods may be embodied in specialized computer hardware.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

The various illustrative logical blocks and modules described in connection with the embodiments disclosed herein can be implemented or performed by a machine, such as a processor. A processor can be a microprocessor, but in the alternative, the processor can be a controller, microcontroller, or state machine, combinations of the same, or the like. A processor can include electrical circuitry configured to process computer-executable instructions. In another embodiment, a processor includes an application specific integrated circuit (ASIC), a field programmable gate array (FPGA) or other programmable device that performs logic operations without processing computer-executable instructions. A processor can also be implemented as a combination of computing devices, e.g., a combination of a digital signal processor (DSP) and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

Conditional language such as, among others, “can,” “could,” “might” or “may,” unless specifically stated otherwise, are otherwise understood within the context as used in general to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Any process descriptions, elements or blocks in the flow diagrams described herein and/or depicted in the attached figures should be understood as potentially representing modules, segments, or portions of code which include one or more executable instructions for implementing specific logical functions or elements in the process. Alternate implementations are included within the scope of the embodiments described herein in which elements or functions may be deleted, executed out of order from that shown, or discussed, including substantially concurrently or in reverse order, depending on the functionality involved as would be understood by those skilled in the art.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C. The same holds true for the use of definite articles used to introduce embodiment recitations. In addition, even if a specific number of an introduced embodiment recitation is explicitly recited, those skilled in the art will recognize that such recitation should typically be interpreted to mean at least the recited number (e.g., the bare recitation of “two recitations,” without other modifiers, typically means at least two recitations, or two or more recitations).

It will be understood by those within the art that, in general, terms used herein, are generally intended as “open” terms (e.g., the term “including” should be interpreted as “including but not limited to,” the term “having” should be interpreted as “having at least,” the term “includes” should be interpreted as “includes but is not limited to,” etc.).

For expository purposes, the term “horizontal” as used herein is defined as a plane parallel to the plane or surface of the floor of the area in which the system being described is used or the method being described is performed, regardless of its orientation. The term “floor” can be interchanged with the term “ground” or “water surface.” The term “vertical” refers to a direction perpendicular to the horizontal as just defined. Terms such as “above,” “below,” “bottom,” “top,” “side,” “higher,” “lower,” “upper,” “over,” and “under,” are defined with respect to the horizontal plane.

As used herein, the terms “attached,” “connected,” “mated” and other such relational terms should be construed, unless otherwise noted, to include removable, moveable, fixed, adjustable, and/or releasable connections or attachments. The connections/attachments can include direct connections and/or connections having intermediate structure between the two components discussed.

Numbers preceded by a term such as “approximately,” “about,” and “substantially” as used herein include the recited numbers, and also represent an amount close to the stated amount that still performs a desired function or achieves a desired result. For example, the terms “approximately,” “about,” and “substantially” may refer to an amount that is within less than 10% of the stated amount. Features of embodiments disclosed herein preceded by a term such as “approximately,” “about,” and “substantially” as used herein represent the feature with some variability that still performs a desired function or achieves a desired result for that feature.

It should be emphasized that many variations and modifications may be made to the above-described embodiments, the elements of which are to be understood as being among other acceptable examples. All such modifications and variations are intended to be included herein within the scope of this disclosure and protected by the following claims.

What is claimed is:

1. An electronic circuit device, comprising:
processing circuitry configured to execute predetermined signal processing; and
a thermometer configured to generate an oscillation signal having an oscillation frequency in correspondence with a temperature of the processing circuitry under a mode:
when the thermometer is driven at a predetermined low power consumption value or less; and
when a thermal resistance between the thermometer and the processing circuitry is a predetermined thermal resistance value or less.

2. The electronic circuit device according to claim 1, wherein the processing circuitry and the thermometer are formed on the same substrate.

3. The electronic circuit device according to claim 1, wherein a sub power supplier configured to feed power to the thermometer is independent of the main power supplier configured to feed power to the processing circuitry.

4. The electronic circuit device according to claim 1, wherein the main power supplier and the thermometer are fed by different power suppliers respectively.

5. The electronic circuit device according to of claim 1, wherein the thermometer comprises an oscillator configured to generate the signal.

6. The electronic circuit device according to claim 5, wherein the oscillator is an RC oscillator.

7. The electronic circuit device according to claim 1, wherein the processing circuitry is further configured to be in at least two states where a power supply is cut off or where an input clock is stopped.

8. The electronic circuit device according to claim 1, wherein the thermometer is further configured to output a real-time clock signal to the processing circuitry.

9. The electronic circuit device according to claim 8, wherein the thermometer is further configured:
to output the real-time clock signal corresponding to the signal in a normal temperature range; and
to output the signal in a temperature measurement temperature range higher than the normal temperature range.

10. The electronic circuit device according to claim 1, wherein the thermometer is further configured:
to generate a temperature measurement signal corresponding to the frequency of
the signal; and
to output the temperature measurement signal to the processing circuitry.

11. The electronic circuit device according to claim 10, wherein the thermometer is further configured:
to input a measurement reference signal having a smaller temperature frequency dependence than the temperature measurement signal; and
to generate the temperature measurement signal from the signal using the measurement reference signal.

12. The electronic circuit device according to claim 1, wherein the processing circuitry is further configured to perform positioning calculation based on a received positioning signal.

13. A method for measuring temperature of an electronic circuit device, comprising:
executing predetermined signal processing;
generating an oscillation signal having an oscillation frequency in correspondence with a temperature of the processing circuitry under a mode:
when the thermometer is driven at a predetermined low power consumption value or less; and
when a thermal resistance between the thermometer and the processing circuitry is a predetermined thermal resistance value or less.

14. The method for measuring the temperature of the electronic circuit device according to claim 13, further comprising:
driving the thermometer at a predetermined low power consumption value or less at a time for a calibration of temperature and frequency.

15. A non-transitory computer-readable storage medium having stored thereon machine-readable instructions that, when executed by one or more processors of an apparatus, cause the apparatus to perform a method comprising:
executing predetermined signal processing;
driving a thermometer at a predetermined low power consumption value or less; and
generating a signal in correspondence with a temperature of the processing circuitry under a mode when a thermal resistance between the thermometer and the processing circuitry is a predetermined thermal resistance value or less.

16. The electronic circuit device according to claim 2, wherein a sub power supplier configured to feed power to the thermometer is independent of the main power supplier configured to feed power to the processing circuitry.

17. The electronic circuit device according to claim 2, wherein the main power supplier and the thermometer are fed by different power suppliers respectively.

18. The electronic circuit device according to of claim 2, wherein the thermometer comprises an oscillator configured to generate the signal.

19. The electronic circuit device according to of claim 3, wherein the thermometer comprises an oscillator configured to generate the signal.

20. The electronic circuit device according to of claim 4, wherein the thermometer comprises an oscillator configured to generate the signal.
